(19) United States
(12) Patent Application Publication
(10) Pub. No.: US 2020/0194297 A1
(43) Pub. Date: Jun. 18, 2020

(54) TRACK SYSTEM AND METHOD OF PROCESSING SEMICONDUCTOR WAFERS

(71) Applicant: XIA TAI XIN SEMICONDUCTOR (QING DAO) LTD., Qingdao (CN)

(72) Inventors: SUNGKUN JANG, Singapore (SG); JONG-KILL LIM, Singapore (SG); BYUNG-IN KWON, Singapore (SG)

(21) Appl. No.: 16/703,506

(22) Filed: Dec. 4, 2019

Related U.S. Application Data
(60) Provisional application No. 62/779,490, filed on Dec. 14, 2018.

(51) Int. Cl. H01L 21/677; H01L 21/687; H01L 21/673

(52) U.S. Cl. CPC H01L 21/67769; H01L 21/67781; H01L 21/6773; H01L 21/67379; H01L 21/68707

(57) ABSTRACT

The present disclosure provides a track system for processing semiconductor wafers held by a plurality of front opening universal pods (FOUPs). The track system includes a process zone, a first common zone, and a second common zone. The process zone includes a first group of process modules and a second group of process modules. The first common zone is coupled to the first group of process modules of the process zone. The first common zone includes a first robot and at least two first FOUP ports. The second common zone is coupled to the second group of process modules of the process zone. The second common zone includes a second robot and at least two second FOUP ports.

### CROSS-REFERENCE TO RELATED APPLICATION(S)

This application claims the benefit of and priority to U.S. Provisional Patent Application No. 62/779,490, filed on Dec. 14, 2018, entitled “METHOD AND TOOL FOR TRANSFERRING WAFERS IN A TRACK TOOL,” with Attorney Docket No. US75632 (hereinafter referred to as “US75632 application”). The disclosure of the US75632 application is hereby incorporated fully by reference into the present application.

### FIELD

The present disclosure generally relates to a track system and a method of processing semiconductor wafers. More specifically, the present disclosure relates to a track system having two common zones integrated, respectively, with two groups of process modules.

### BACKGROUND

A wafer is processed in several different tools for performing various fabrication functions in a semiconductor fabrication plant. In order to enhance the throughput of wafers in the semiconductor fabrication plant, productivity enhancement of tools is important. Furthermore, the space in a semiconductor fabrication plant is limited. Efficient tool arrangement may save the space in the semiconductor fabrication plant while providing increased productivity.

A track tool or a track system is an equipment cluster for semiconductor manufacturing processes. A track tool may include front opening universal pod (FOUP) ports (also known as front opening unified pod ports or cassette ports), process modules, common zones, and transfer robots. The track tool may be used to perform various semiconductor manufacturing processes, such as a spin on coating (SOC) process in photolithography processes, a spin on dielectric (SOD) process in thin film formation processes, or a cleaning process in wet etching processes. A FOUP that holds a plurality of wafers (e.g., 25 wafers in a FOUP) is loaded to and unloaded from the FOUP port of the track tool. The wafers are then transferred from the FOUP to a process module of the track tool by the transfer robots in a common area of the track tool. The wafer is processed in the process module.

In order to enhance the productivity in the track tool, the amount of the process module may be increased. However, the transfer robot arranged in the common area causes a bottleneck in increasing productivity, because certain limitations are applied to the time for the transfer robot to transfer a wafer from the FOUP to a process module, and the transfer robot in the common area is controlled to perform its task at a certain pace to avoid mishandling (e.g., wafer damage) issues. If a processed wafer is pending in the process module and the transfer robot is still handling another wafer (in another process module), the processed wafer may be idling in the process module, and the productivity is decreased.

Accordingly, there remains a need to improve the productivity of a tack tool for processing semiconductor wafers.

### SUMMARY OF THE DISCLOSURE

In view of above, an object of the present disclosure is to provide a track system and a method of processing semiconductor wafers to improve the productivity of processing wafers.

To achieve the above object, an embodiment of the present disclosure provides a track system for processing semiconductor wafers held by a plurality of front opening universal pods (FOUPs). The track system includes a process zone, a first common zone, and a second common zone. The process zone includes a first group of process modules and a second group of process modules. Each of the process modules is configured to process the wafers. The first common zone is coupled to the first group of process modules of the process zone. The first common zone includes a first robot and at least two first FOUP ports. Each of the first FOUP ports is configured to be disposed with one of the FOUPs. The first robot is configured to transfer the wafers between the FOUPs disposed at the first FOUP ports and the first group of process modules. The second common zone is coupled to the second group of process modules of the process zone. The second common zone includes a second robot and at least two second FOUP ports. Each of the second FOUP ports is configured to be disposed with one of the FOUPs. The second robot is configured to transfer the wafers between the FOUPs disposed at the second FOUP ports and the second group of process modules.

To achieve the above object, another embodiment of the present disclosure provides a method of processing semiconductor wafers held by a plurality of FOUPs. The method includes steps S801 to S810. In step S801, the FOUPs are loaded to a track system. The track system includes a process zone, a first common zone, and a second common zone. The process zone includes a first group of process modules and a second group of process modules. The first common zone includes a first robot and at least two first FOUP ports. The second common zone includes a second robot and at least two second FOUP ports. The first FOUP ports and the second FOUP ports are configured to be disposed with the FOUPs. In step S802, the wafers are unloaded from the FOUPs disposed at the first FOUP ports by the first robot, and from the FOUPs disposed at the second FOUP ports by the second robot. In step S803, the wafers from the FOUPs disposed at the first FOUP ports are transferred to the first group of process modules by the first robot; and the wafers from the FOUPs disposed at the second FOUP ports are transferred to the second group of process modules by the second robot. In steps S804 to S808, the wafers are processed in the first group and the second group of process modules. In step S809, the wafers are removed from the first group of process modules by the first robot, and from the second group of process modules by the second robot. In step S810, the wafers are loaded to the FOUPs disposed at the first FOUP ports by the first robot, and loaded to the FOUPs disposed at the second FOUP ports by the second robot.

As described above, the track system according to the embodiments of the present disclosure has two common zones integrated, respectively, with two groups of process modules. The track system allows full utilization of the space of the process zone in the track system. Therefore, the track system of the embodiments of the present disclosure increases productivity and space efficiency.

### BRIEF DESCRIPTION OF THE DRAWINGS

Implementations of the present technology will now be described, by way of example only, with reference to the attached figures.

FIG. 1 is a schematic diagram of a track system for processing wafers according to an example embodiment of the present disclosure.

FIG. 2 is a schematic flow of a coating process in photolithography processes according to an example embodiment of the present disclosure.

FIG. 3 is a schematic flow of a coating process in photolithography processes according an example embodiment of the present disclosure.

FIG. 4 is a schematic flow of a cleaning process according to an example embodiment of the present disclosure.

FIG. 5 is a schematic diagram of a track system for processing wafers according to an example embodiment of the present disclosure.

FIGS. 6A and 6B are a schematic flow and a flowchart of a method of processing semiconductor wafers according to an example embodiment of the present disclosure.

FIG. 7 is a schematic diagram of a track system for processing wafers according to an example embodiment of the present disclosure.

FIGS. 8A and 8B are a schematic flow and a flowchart of a method of processing semiconductor wafers according to an example embodiment of the present disclosure.

FIG. 9 is a chart showing productivities of the track system of the example embodiments described in FIGS. 1, 5, and 7.

FIG. 10 is a schematic diagram showing the arrangement of the track system described in FIG. 7 in a semiconductor fabrication plant.

### DETAILED DESCRIPTION

The present disclosure will now be described more fully hereinafter with reference to the accompanying drawings, in which exemplary embodiments of the disclosure are shown. This disclosure may, however, be embodied in many different forms and should not be construed as limited to the exemplary embodiments set forth herein. Rather, these exemplary embodiments are provided so that this disclosure will be thorough and complete, and will fully convey the scope of the disclosure to those skilled in the art. Like reference numerals refer to like elements throughout.

The terminology used herein is for the purpose of describing particular exemplary embodiments only and is not intended to be limiting of the disclosure. As used herein, the singular forms “a”, “an” and “the” are intended to include the plural forms as well, unless the context clearly indicates otherwise. It will be further understood that the terms “comprises” and/or “comprising,” or “includes” and/or “including” or “has” and/or “having” when used herein, specify the presence of stated features, regions, integers, steps, operations, elements, and/or components, but do not preclude the presence or addition of one or more other features, regions, integers, steps, operations, elements, components, and/or groups thereof.

It will be understood that the term “and/or” includes any and all combinations of one or more of the associated listed items. It will also be understood that, although the terms first, second, third etc. may be used herein to describe various elements, components, regions, parts and/or sections, these elements, components, regions, parts and/or sections should not be limited by these terms. These terms are only used to distinguish one element, component, region, part or section from another element, component, region, layer or section. Thus, a first element, component, region, part or section discussed below could be termed a second element, component, region, layer or section without departing from the teachings of the present disclosure.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

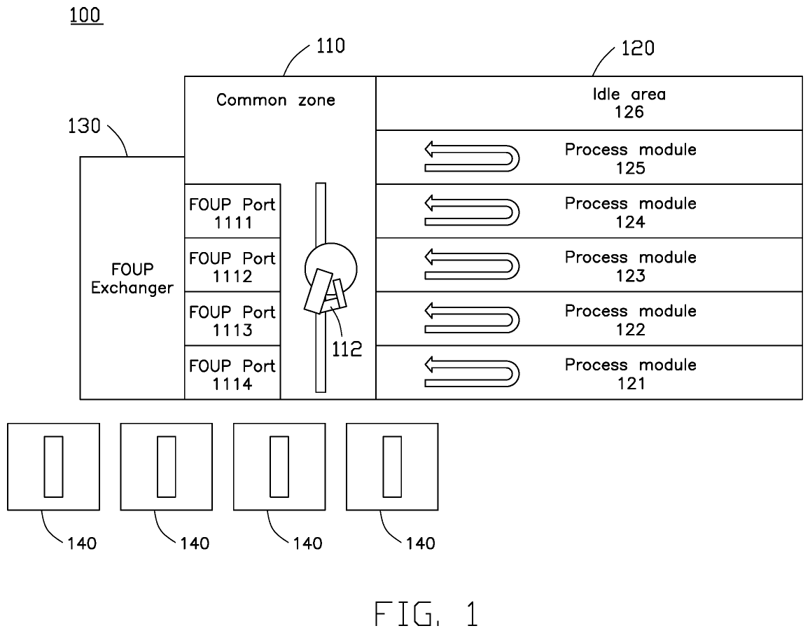

The description will be made as to the exemplary embodiments of the present disclosure in conjunction with the accompanying drawings in FIGS. 1 to 10. Reference will be made to the drawing figures to describe the present disclosure in detail, wherein depicted elements are not necessarily shown to scale and wherein like or similar elements are designated by same or similar reference numeral through the several views and same or similar terminology.

The present disclosure will be further described hereafter in combination with the accompanying figures.

Referring to FIG. 1, a schematic diagram of a track system 100 for processing wafers, according to an example embodiment of the present disclosure is illustrated. As shown in FIG. 1, the track system 100 includes a common zone 110 and a process zone 120 having five process modules 121 to 125 and one idle area 126. The common zone 110 includes a robot 112 and four front opening universal pod (FOUP) ports 1111 to 1114. Each of the process modules 121 to 125 in the process zone 120 may include a plurality of units. Each of the units is used to perform a semiconductor manufacturing process such as adhesion (ADH) process, spin on coating (SOC), post apply baking (PAB), or chill plate (CPL) process. The idle area 126 is a spare area that is not used for wafer processing, since the robot transfer has a limited transfer rate and is not capable of transferring wafers for six process modules. A front opening universal pod (FOUP) 140 accommodating a plurality of wafers (e.g., 25 wafers in one FOUP) is loaded to one of the FOUP ports 1111 to 1114, and then the robot 112 transfers the wafers from the FOUP 140 to one of the process modules 121 to 125 in the process zone 120. After the wafers are completed with the processes in the process zone 120, the robot 112 transfers the wafers from the process zone 120 to the FOUP 140, and then the FOUP 140 is unloaded from one of the FOUP ports 1111 to 1114.

In one embodiment, the FOUP 140 is loaded to one of the FOUP ports 1111 and 1112 (i.e. the FOUP ports 1111 and 1112 are inbound FOUP ports used for loading the FOUP 140 carrying unprocessed wafers). After all the wafers in the FOUP 140 are transferred to the process zone 120, the FOUP 140 is then transferred from one of the inbound FOUP ports 1111 and 1112 to one of the other FOUP ports 1113 and 1114. The FOUP 140 is unloaded from one of the FOUP ports 1113 and 1114 (i.e., the FOUP ports 1113 and 1114 are outbound FOUP ports used for unloading the FOUP 140 carrying processed wafers). A FOUP exchanger 130 may be installed adjacent to the FOUP ports 1111 to 1114 of the common zone 110. The FOUP exchanger 130 is configured to supply FOUPs to the track system 100.

For example, in order to process six hundred wafers per hour in the track system 100, the wafer unloading time of the robot 112 (i.e., the time for the robot 112 to transfer an unprocessed wafer from the FOUP 140 to one of the process modules 121 to 125 of the process zone 120) is set as 3 seconds. The wafer loading time of the robot 112 (i.e., the time for the robot to transfer a processed wafer from the process zone 120 to the FOUP 140) is also set as 3 seconds. Mechanical limitations of the track system 100 make it difficult to further reduce the wafer processing time to less than 3 seconds, because the possibility of wafer damage in the process modules 121 to 125 of the process zone 120 might be increased. Also, 3 seconds is the minimal time for the robot 112 to unload or load the wafer. As a result, it is difficult to have six process modules (e.g., if a sixth process module is installed in the idle area 126) for processing the wafers. The limited processing capability of the robot 112 hinders the effective utilization of an additional process module (e.g., since the processed wafers may have been forced to stay in the process modules and wait for the robot 112 to finish its previous task, for example, from the previous process module to the FOUP). In the illustrated example of FIG. 1, only one robot 112 is used for four FOUP ports 1111 to 1114 and five process modules 121 to 125 in the track system 100. In order to process 600 wafers per hour, a FOUP (which is capable of holding 25 wafers) needs to be exchanged to a next FOUP within no more than 150 seconds by the FOUP exchanger 130. The FOUP exchanger 130 facilitates the exchanging of FOUPs to maintain the processing rate at 600 wafers per hour. However, the FOUP exchanger 130 occupies the space of a semiconductor fabrication plant.

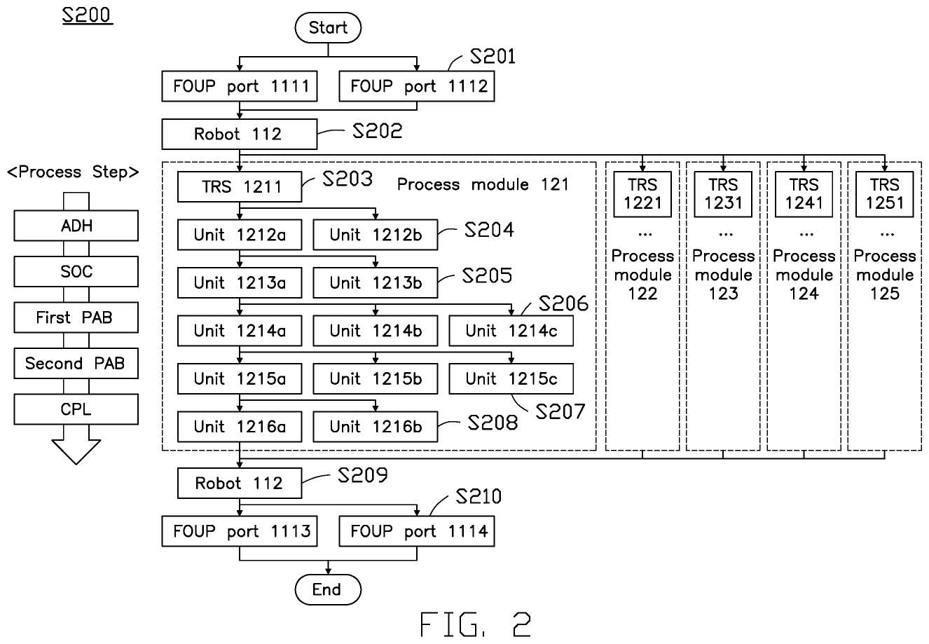

Referring to FIG. 2, a schematic flow of a coating process S200 according to an example embodiment of the present disclosure is illustrated. The coating process S200 is performed by the track system 100 of FIG. 1. In this embodiment, each of the process modules 121 to 125 includes a plurality of units to perform an adhesion (ADH) process, a spin on coating (SOC) process, at least one post apply baking (PAB) process (e.g., a first PAB process and a second PAB process), and a chill plate (CPL) process. As shown in FIG. 2, the process module 121 (or any other one of the process modules 122-125) includes units 1212a and 1212b to perform the ADH process, units 1213a and 1213b to perform the SOC process, units 1214a to 1214c to perform the first PAB process, units 1215a to 1215c to perform the second PAB process, and units 1216a and 1216b to perform the CPL process. Each unit in the same process has the same function. Each of the process modules 121 to 125 may further include a transition stage (TRS) 1211 to 1251, respectively. Each of the TRSs is configured to temporarily hold the wafer before the wafers are transferred to the units.

As shown in FIG. 2, the coating process S200 includes steps S201 to S210. In step 201, a FOUP carrying a plurality of wafers (e.g., 25 wafers) is loaded to one of the FOUP ports 1111 and 1112. In step S202, a wafer is unloaded from the FOUP by the robot 112. In step S203, the wafer is transferred to a transition stage (TRS) of one of the process modules (e.g., TRS 1211 of the process module 121).

In step S204, the wafer is transferred to one of the units in each of the process modules to perform the ADH process (e.g., units 1212a and 1212b of the process module 121). Each of the units performing the ADH process (e.g., units 1212a and 1212b of the process module 121) includes a deposition device and a chilling device. In the deposition device, an adhesion promoting layer, such as hexamethyl disilazane (HMDS), is formed on the surface of the wafer. The wafer may be chilled on the chilling device before or after the adhesion promoting layer is formed on the wafer.

In step S205, the wafer is transferred to one of the units in each of the process modules to perform the SOC process (e.g., units 1213a and 1213b in the process module 121). Each of the units performing the SOC process (e.g., units 1213a and 1213b in the process module 121) includes a coating device. During the SOC process, a layer, such as Bottom Anti-Reflective Coating (BARC), is formed on the surface of the wafer. Alternatively, a spin on a dielectric layer, such as organic spin-on dielectric material, is formed over the wafer in the coating device during SOC process.

In step S206, the wafer is transferred to one of the units in each of the process modules to perform the first PAB process (e.g., units 1214a, 1214b and 1214c in the process module 121). Each of the units performing the first PAB process (e.g., units 1214a, 1214b and 1214c in the process module 121) includes a heating device and a chilling device. During the first PAB process, the wafer is baked on the heating device. The wafer may be chilled on the chilling device before or after the wafer is baked on the heating device.

In step S207, the wafer is transferred to one of the units in each of the process modules to perform the second PAB process (e.g., units 1215a, 1215b and 1215c in the process module 121). Each of the units performing the second PAB process (e.g., units 1215a, 1215b and 1215c in the process module 121) includes a heating device and a chilling device. During the second PAB process, the wafer is baked on the heating device. The temperature of the second PAB process is higher than that of the first PAB process. The wafer may be chilled on the chilling device before or after the wafer is baked on the heating device.

In step S208, the wafer is transferred to one of the units in each of the process modules to perform the CPL process (e.g., units 1216a and 1216b in the process module 121). Each of the units performing the CPL process (e.g., units 1216a and 1216b in the process module 121) includes a chill plate. During the CPL process, the wafer chills on the chilling plate.

In step S209, the wafer is transferred from one of the process modules to the robot 112. In step S210, the wafer is loaded to a FOUP at one of the FOUP ports 1113 and 1114. The FOUP at the FOUP port 1113 or 1114 may be the same FOUP at the FOUP port 1111 or 1112. When all the unprocessed wafers in the FOUP at the FOUP port 1111 or 1112 are transferred to one of the process modules, the empty FOUP is then transferred from the inbound FOUP port 1111 or 1112 to the outbound FOUP port 1113 or 1114 for loading processed wafers. The series of steps performed in each of the process modules are identical.

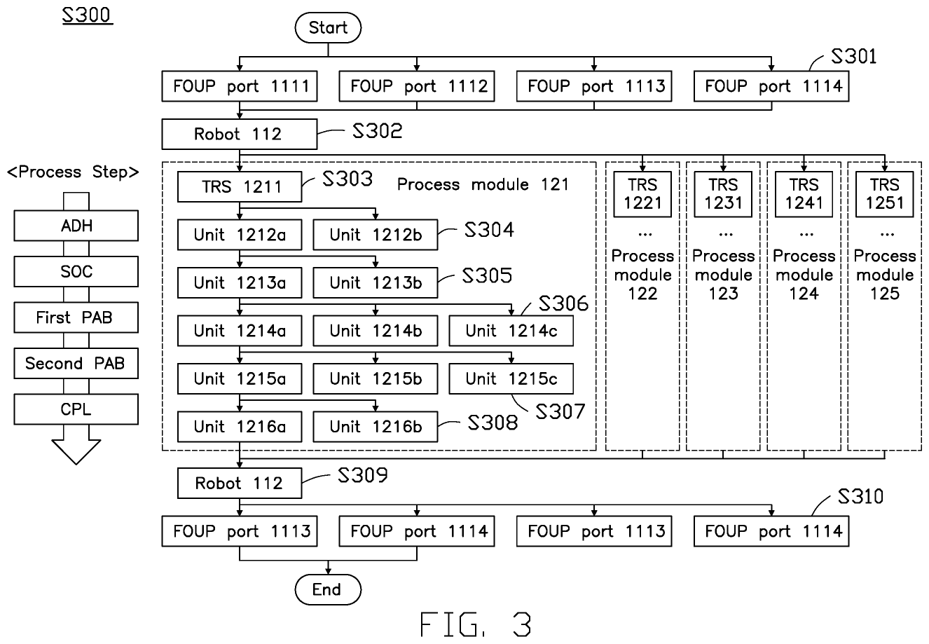

Referring to FIG. 3, a schematic flow of a coating process S300 according to an example embodiment of the present disclosure is illustrated. The coating process S300 is performed by the track system 100 of FIG. 1. The process modules 121 to 125 shown in FIG. 3 are identical to those shown in FIG. 2 without further description herein. As shown in FIG. 3, the coating process S300 shown in FIG. 3 includes steps S301 to S310. In step S301, a FOUP carrying a plurality of wafers (e.g., 25 wafers) is loaded to one of the FOUP ports 1111 to 1114. The steps S302 to S309 are similar to the steps S202 to S209 of described with reference to FIG. 2 without further description herein. In step S310, the wafer is loaded to a FOUP at one of the FOUP ports 1111 to 1114. In some of the embodiments, each of the FOUP ports 1111 to 1114 functions as both an inbound FOUP port and an outbound FOUP port. In other words, the FOUP carrying unprocessed wafers may be disposed on one of the FOUP ports 1111 to 1114. When all the unprocessed wafers are transferred to the process zone 120, the FOUP remains at the FOUP ports, and the wafers may be transferred back into the FOUP after being processed in the process zone 120. For example, if a FOUP carrying unprocessed wafers is disposed at the FOUP port 1111, the processed wafer from the FOUP may be transferred back into the FOUP disposed at the FOUP port 1111.

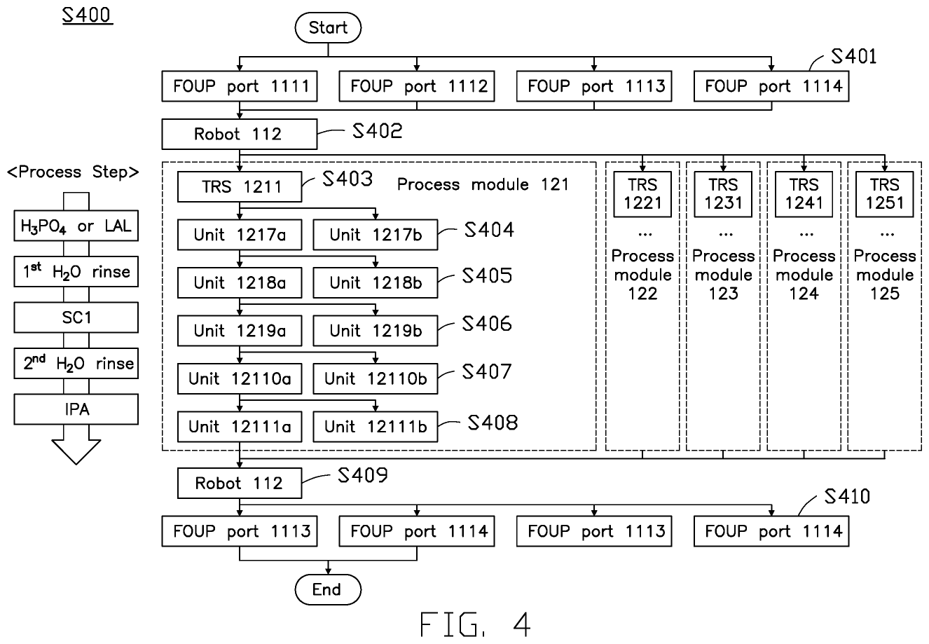

Referring to FIG. 4, a schematic flow of a cleaning process S400 according to an example embodiment of the present disclosure is illustrated. The cleaning process S400 may be a process in a wet etching process. The cleaning process S400 is performed by the track system 100 of FIG. 1. In some embodiments, each of the process modules 121 to 125 includes a plurality of units for cleaning the wafers by a cleaning agent, such as a Standard Cleaning 1 (SC1) solution, a Buffered Oxide Etch (BOE) solution, a low ammonium fluoride liquid (LAL) solution, an H₃PO₄ solution, or a Sulfuric Peroxide Mixture (SPM) solution. As shown in FIG. 4, using the process module 121 as an example, the process module 121 includes units 1217a and 1217b to clean the wafers by the H₃PO₄ solution or LAL solution, units 1218a and 1218b to rinse the wafers by the deionized (DI) water, units 1219a and 1219b to clean the wafers by the SC1 solution, units 12110a and 12110b to rinse the wafers by the DI water, and units 12111a and 12111b to rinse the wafers by the isopropyl alcohol (IPA). Each unit in the same process has the same function. Each of the process modules 121 to 125 may further include a transition stage (TRS) 1211 to 1251, respectively. Each of the TRSs is configured to temporarily hold the wafers before the wafers are transferred to the units.

As shown in FIG. 4, the cleaning process S400 includes steps S401 to S410. The steps S401 to S403 are similar to the steps S301 to S303 of shown in FIG. 3 without further description herein. In step S404, the wafers are transferred to one of the units in each of the process modules to be cleaned by the H₃PO₄ solution or LAL solution (e.g., units 1217a and 1217b in the process module 121). In step S405, the wafers are transferred to one of the units in each of the process modules to be rinsed by the DI water (e.g., units 1218a and 1218b in the process module 121). In step S406, the wafers are transferred to one of the units in each of the process modules to be cleaned by the SC1 solution (e.g., units 1219a and 1219b in the process module 121). In step S407, the wafers are transferred to one of the units in each of the process modules to be rinsed by the DI water (e.g., units 12110a and 12110b in the process module 121). In step S408, the wafers are transferred to one of the units in each of the process modules to be rinsed by the IPA (e.g., units 12111a and 12111b in the process module 121). In steps S404 to S408, each of the units may include a cleaning tank to clean the wafers. The steps S409 and S410 are similar to the steps S309 and S310 described with reference to FIG. 3 without further description herein.

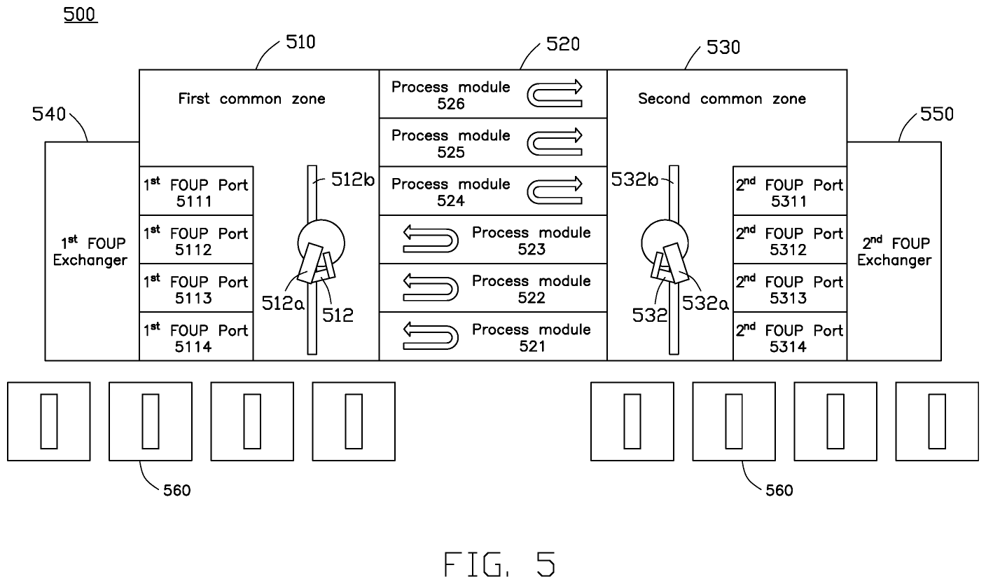

Referring to FIG. 5, a schematic diagram of a track system 500 for processing semiconductor wafers held by a plurality of FOUPs 560 according to an example embodiment of the present disclosure are illustrated. The track system 500 may be used for a spin on coating (SOC) process in photolithography processes, a spin on dielectric (SOD) process in thin film formation processes, or a cleaning process in wet etching processes. As shown in FIG. 5, the track system 500 includes a process zone 520, a first common zone 510 and a second common zone 530. The process zone 520 includes a first group of process modules and a second group of process modules. In this embodiment, the first group of process modules includes three process modules 521, 522, 523, and the second group of process modules includes three process modules 524, 525, 526. Each of the process modules 521 to 526 is configured to process the wafers. The first common zone 510 is coupled to the first group of process modules 521 to 523 in the process zone 520, and includes a first robot 512 and at least two first FOUP ports. Each of the FOUP ports is configured to be disposed with one of the FOUPs 560. The first robot 512 is configured to transfer the wafers between the FOUPs 560 disposed at the first FOUP ports and the first group of process modules 521 to 523. The second common zone 530 is coupled to the second group of process modules 524 to 526 in the process zone 520, and includes a second robot 532 and at least two second FOUP ports. Each of the first FOUP ports is configured to be disposed with one of the FOUPs 560. The second robot 532 is configured to transfer the wafers between the FOUPs 560 disposed at the second FOUP ports and the second group of process modules 524 to 526.

In some embodiments, the at least two first FOUP ports include at least one inbound FOUP port and at least one outbound FOUP port. Preferably, the at least two first FOUP ports include two inbound FOUP ports 5111, 5112 and two outbound FOUP ports 5113, 5114. The inbound FOUP ports 5111, 5112 are configured to be disposed with the FOUPs 560 holding unprocessed wafers, and the outbound FOUP ports 5113, 5114 are configured to be disposed with the FOUPs 560 holding processed wafers. The at least two second FOUP ports include at least one inbound FOUP port and at least one outbound FOUP port. Preferably, the at least two second FOUP ports include two inbound FOUP ports 5311, 5312 and two outbound FOUP ports 5313, 5314.

The process zone 520 has a first side and a second side parallel to the first side. The first FOUP ports 5111 to 5114 of the first common zone 510 are disposed along the first side of the process zone 520. The second FOUP ports 5311 to 5314 of the second common zone 530 are disposed along the second side of the process zone 520. The first robot 512 includes a guiding rail 512b and a robot hand 512a coupled to the guiding rail 512b. The second robot 532 also includes a guiding rail 532b and a robot hand 532a coupled to the guiding rail 532b. Each of the robot hands 512a, 532a is configured to move the wafers along the guiding rails 512b, 532b, respectively. Each of the process modules 521 to 526 in the first and the second group includes a plurality of units configured to process the wafers. In one embodiment, each of the units of the process modules 521 to 526 is configured to perform at least one of an adhesion (ADH) process, a spin on coating (SOC) process, at least one post apply baking (PAB) process (e.g., a first PAB process and a second PAB process), and a chill plate (CPL) process. Each of the process modules 521 to 526 may further include a transition stage (TRS) configured to be disposed with the wafers before the wafers are transferred to the units.

In the example illustrated in FIG. 5, the track system 500 may further include a first FOUP exchanger 540 coupled to the first common zone 510 and configured to exchange the FOUPs 560 among the first FOUP ports 5111 to 5114. The track system 500 may further include a second FOUP exchanger 550 coupled to the second common zone 530 and configured to exchange the FOUPs 560 among the second FOUP ports 5311 to 5314. Using the first common zone 510 as an example, the FOUPs carrying unprocessed wafers are loaded to one of the inbound FOUP ports (i.e., first FOUP ports 5111, 5112). The wafers in the FOUPs disposed at the first FOUP ports 5111, 5112 are transferred to the first group of process modules 521 to 523 by the first robot 512. When all the wafer in the FOUPs disposed at the first FOUP ports 5111, 5112 are transferred to the process zone 520, the FOUPs are transferred to the outbound FOUP ports (i.e., first FOUP ports 5113, 5114) by the first FOUP exchanger 540. The wafers processed by the first group of process modules 521 to 523 are then loaded to the FOUPs disposed at the outbound FOUP ports (i.e., first FOUP ports 5113, 5114) by the first robot 512. When the FOUPs at the outbound FOUP ports are filled with processed wafers, the FOUPs are removed from the outbound FOUP ports. Likewise, the details on the operations of the second common zone 530 are similar to those of the first common zone 510.

Compared to the illustrated example of FIG. 1 (i.e., five process modules are installed), the track system 500 shown in FIG. 5 fully utilizes all space in the process zone 520 (i.e., six process modules are installed). The track system 500 shown in FIG. 5 may increase the wafer processing rate by 20%. Furthermore, in the illustrated example of FIG. 5, since the speed of the first robot 512 and the second robot 532 is no longer a bottleneck for the wafer processing, the transferring time of the first robot 512 and the second robot 532 may be set at more than 3 seconds (such as 4 to 6 seconds) to decrease the possibility of wafer breakage issues. Therefore, the track system 500 shown in FIG. 5 increases productivity of wafer processing as compared to the track system 100 shown in FIG. 1.

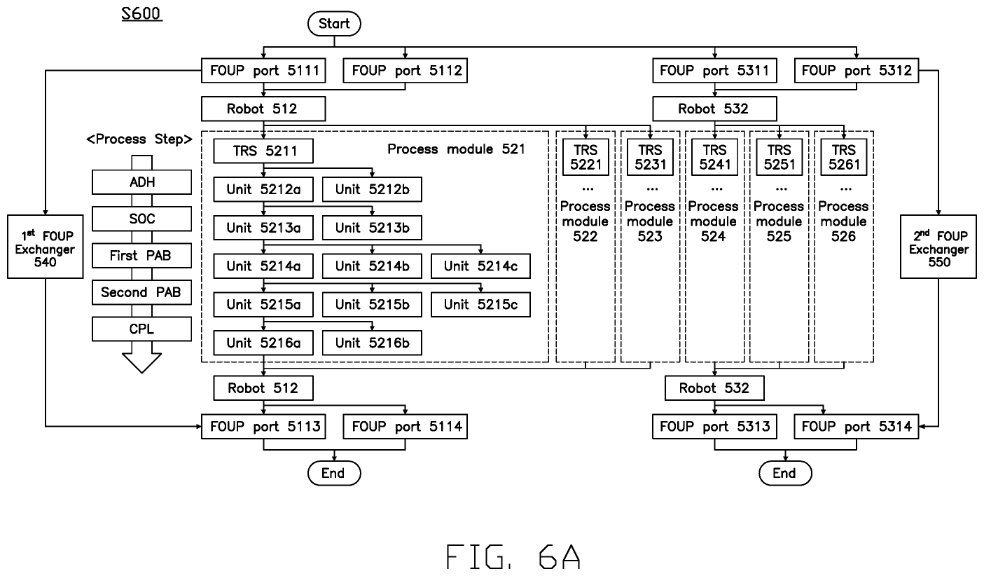

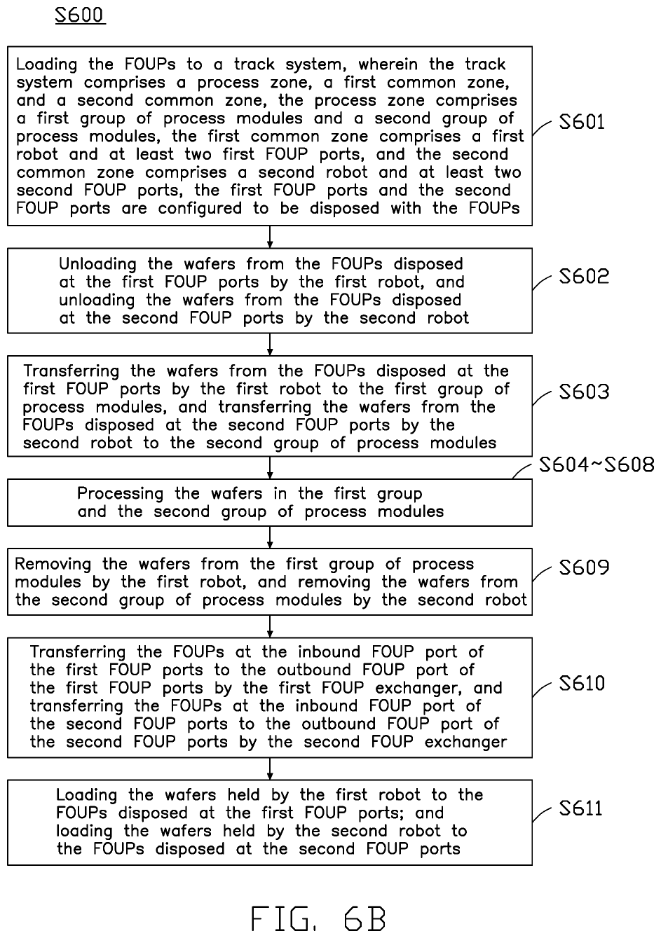

Referring to FIGS. 6A and 6B, a schematic flow and a flowchart of a method S600 of processing semiconductor wafers held by a plurality of FOUPs according to an example embodiment of the present disclosure are illustrated. The method S600 shown in FIGS. 6A and 6B includes steps S601 to S611. In step S601, the FOUPs are loaded to a track system. The track system of the illustrated example of FIGS. 6A and 6B is similar to the track system 500 shown in FIG. 5. The track system 500 includes a process zone 520, a first common zone 510, and a second common zone 530. The process zone 520 includes a first group of process modules 521 to 523 and a second group of process modules 524 to 526. The first common zone 510 comprises a first robot 512 and at least two first FOUP ports 5111 to 5114. The second common zone 530 includes a second robot 532 and at least two second FOUP ports 5311 to 5314. The first FOUP ports 5111 to 5114 and the second FOUP ports 5311 to 5314 are configured to be disposed with the FOUPs 560. The at least two first FOUP ports include at least one inbound FOUP port (i.e., FOUP ports 5111, 5112) and at least one outbound FOUP port (i.e., FOUP ports 5113, 5114). The at least two second FOUP ports include at least one inbound FOUP port (i.e., FOUP ports 5311, 5312) and at least one outbound FOUP port (i.e., FOUP ports 5313, 5314). The inbound FOUP port (i.e., each of the FOUP ports 5111, 5112, 5311, 5312) is configured to be disposed with the FOUPs 560 holding unprocessed wafers. The outbound FOUP port (i.e., each of the FOUP ports 5113, 5114, 5313, 5314) is configured to be disposed with the FOUPs 560 holding processed wafers. The FOUPs 560 are loaded to the inbound FOUP ports (i.e., FOUP ports 5111, 5112, 5311, 5312) of the track system 500. The track system 500 further includes a first FOUP exchanger 540 coupled to the first common zone 510 and a second FOUP exchanger 550 coupled to the second common zone 530.

In step S602, the wafers are unloaded from the FOUPs 560 disposed at the first FOUP ports (i.e., FOUP ports 5111, 5112) by the first robot 512, and unloaded from the FOUPs disposed at the second FOUP ports (i.e., FOUP ports 5311, 5312) by the second robot 532.

In step S603, the wafers from the FOUPs 560 disposed at the first FOUP ports (i.e., FOUP ports 5111, 5112) are transferred to the first group of process modules 521 to 523 by the first robot 512, and wafers from the FOUPs disposed at the second FOUP ports (i.e., FOUP ports 5311, 5312) are transferred to the second group of process modules 524 to 526 by the second robot 532. Each of the process modules 521 to 526 includes a transition stage (TRS) 5211 to 5261, respectively. The wafers are transferred to the TRS 5211 to 5261 in each of the process modules 521 to 526.

In steps S604 to S608, the wafers are processed in the first group and the second group of process modules 521 to 526. As shown in FIG. 6A, each of the process modules 521 to 526 includes a plurality of units to perform an adhesion (ADH) process, a spin on coating (SOC) process, at least one post apply baking (PAB) process (e.g., a first PAB process and a second PAB process), and a chill plate (CPL) process. Using the process module 521 as an example, the process module 521 includes units 5212a and 5212b to perform the ADH process, units 5213a and 5213b to perform the SOC process, units 5214a to 5214c to perform the first PAB process, units 5215a to 5215c to perform the second PAB process, and units 5216a and 5216b to perform the CPL process. Each unit in the same process has the same function. In one embodiment, the processing recipe of the first group of process modules 521 to 523 may be identical to that of the second group of process modules 524 to 526. The process recipe may include processing sequence of the units, processing time, processing temperature, processing chemicals, spinning speed, and so forth. In another embodiment, the process recipe of the first group of process modules 521 to 523 may be different from that of the second group of process modules 524 to 526. Also, the process recipe of the first group of process modules 521 to 523 may be identical to or different from each other. The process recipe of the second group of process modules 524 to 526 may be identical to or different from each other.

In step S604, the wafer is transferred to one of the units in each of the process modules to perform the ADH process (e.g., units 5212a and 5212b in the process module 521). Each of the units performing the ADH process (e.g., units 5212a and 5212b in the process module 521) includes a deposition device and a chilling device. In the deposition device, an adhesion promoting layer, such as hexamethyl disilazane (HMDS), is formed on the surface of the wafer. The wafer may be chilled on the chilling device before or after the adhesion promoting layer is formed on the wafer.

In step S605, the wafer is transferred to one of the units in each of the process modules to perform the SOC process (e.g., units 5213a and 5213b in the process module 521). The units performing the SOC process (e.g., units 5213a and 5213b in the process module 521) includes a coating device. During the SOC process, a layer such as Bottom Anti-Reflective Coating (BARC) is formed on the surface of the wafer. Alternatively, a spin on dielectric layer such as organic spin-on dielectric material is formed over the wafer in the coating device during the SOC process.

In step S606, the wafer is transferred to one of the units in each of the process modules to perform the first PAB process (e.g., units 5214a, 5214b and 5214c in the process module 521). Each of the units performing the first PAB process (e.g., units 5214a, 5214b and 5214c in the process module 521) includes a heating device and a chilling device. During the first PAB process, the wafer is baked on the heating device. The wafer may be chilled on the chilling device before or after the wafer is baked on the heating device.

In step S607, the wafer is transferred to one of the units in each of the process modules to perform the second PAB process (e.g., units 5215a, 5215b and 5215c in the process module 521). Each of the units performing the second PAB process (e.g., units 5215a, 5215b and 5215c in the process module 521) includes a heating device and a chilling device. During the second PAB process, the wafer is baked on the heating device. The temperature of the second PAB process is higher than that of the first PAB process. The wafer may be chilled on the chilling device before or after the wafer is baked on the heating device.

In step S608, the wafer is transferred to one of the units in each of the process modules to perform the CPL process (e.g., units 5216a and 5216b in the process module 521). Each of the units performing the CPL process (e.g., units 5216a and 5216b in the process module 521) includes a chill plate. During the CPL process, the wafer chills on the chilling plate.

In step S609, the wafers are removed from the first group of process modules 521 to 523 by the first robot 512, and from the second group of process modules 524 to 526 by the second robot 532.

In step S610, the FOUPs 560 at the inbound port of the first FOUP ports (i.e., FOUP ports 5111, 5112) are transferred to the outbound port of the first FOUP ports (i.e., FOUP ports 5113, 5114) by the first FOUP exchanger 540, and the FOUPs 560 at the inbound port of the second FOUP ports (i.e., FOUP ports 5311, 5312) are transferred to the outbound port of the second FOUP ports (i.e., FOUP ports 5313, 5314). When all the wafers in a FOUP are transferred to the process zone 520, the FOUP in the inbound port is transferred to the outbound port by the first FOUP exchanger 540 and the second FOUP exchanger 550.

In step S611, the processed wafers held by the first robot 512 are loaded to the FOUPs 560 disposed at the first FOUP ports, and the processed wafer held by the second robot 532 are loaded to the FOUPs 560 disposed at the second FOUP ports. Specifically, the processed wafers held by the first robot 512 are loaded to the FOUP disposed at the outbound FOUP port of the first FOUP ports (i.e., FOUP ports 5113, 5114), and the processed wafers held by the second robot 532 are loaded to the FOUPs 560 disposed at the outbound FOUP ports of the second FOUP ports (i.e., FOUP ports 5313, 5314).

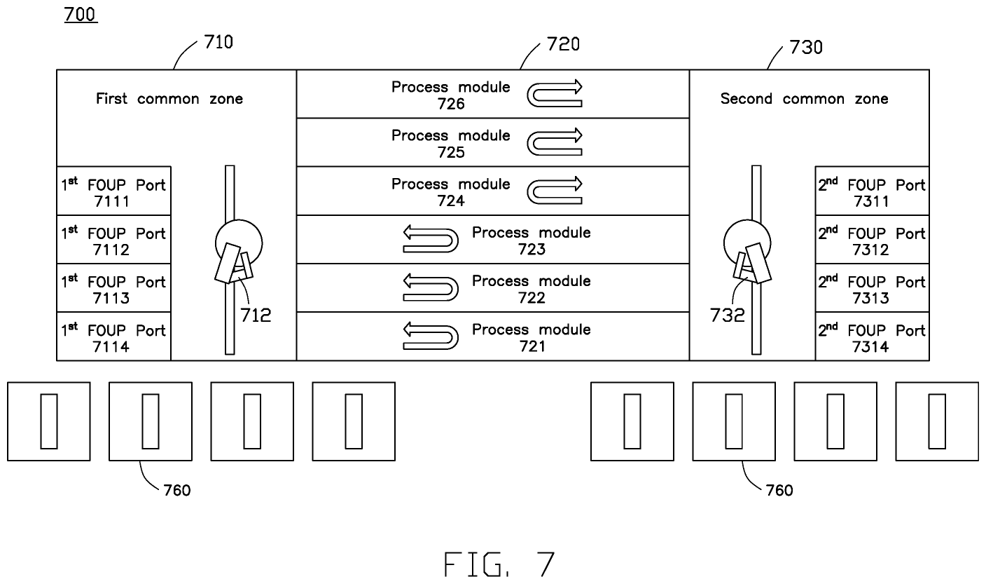

Referring to FIG. 7, a schematic diagram of a track system 700 for processing semiconductor wafers held by a plurality of FOUPs 760 according to an example embodiment of the present disclosure is illustrated. As shown in FIG. 7, the track system 700 includes a process zone 720, a first common zone 710 and a second common zone 730. The process zone 720 includes a first group of process modules and a second group of process modules. In this embodiment, the first group of process modules includes three process modules 721, 722, 723; and the second group of process modules includes three process modules 724, 725, 726. Each of the process modules 721 to 726 is configured to process the wafers. The first common zone 710 is coupled to the first group of process modules 721 to 723 of the process zone 720, and includes a first robot 712 and at least two first FOUP ports. Each of the FOUP ports is configured to be disposed with one of the FOUPs 760. The first robot 712 is configured to transfer the wafers between the FOUPs 760 disposed at the first FOUP ports and the first group of process modules 721 to 723. The second common zone 730 is coupled to the second group of process modules 724 to 726 of the process zone 720, and includes a second robot 732 and at least two second FOUP ports. Each of the first FOUP ports is configured to be disposed with one of the FOUPs 760. The second robot 732 is configured to transfer the wafers between the FOUPs 760 disposed at the second FOUP ports and the second group of process modules 724 to 726. In the illustrated example of FIG. 7, the first FOUP ports include four FOUP ports 7111, 7112, 7113, 7114, and the first group of process modules includes three process modules 721, 722, 723. The second FOUP ports include four FOUP ports 7311, 7312, 7313, 7314, and the second group of the process modules includes three process modules 724, 725, 726. Each of the first FOUP ports (i.e., FOUP ports 7111 to 7114) and the second FOUP ports (i.e., FOUP ports 7311 to 7314) functions as an inbound FOUP port for disposing the FOUPs holding a plurality of unprocessed wafers and an outbound FOUP port for disposing the FOUPs holding processed wafers.

In some embodiments, the unprocessed wafers in the FOUPs 760 disposed at the first FOUP ports 7111 to 7114 are transferred to the first group of process modules 721 to 723 by the first robot 712. The processed wafers from the first group of process modules 721 to 723 are then transferred back to their original FOUPs 760 disposed at the first FOUP ports 7111 to 7114 by the first robot 712. The unprocessed wafers in the FOUPs 760 disposed at the second FOUP ports 7311 to 7314 are transferred to the second group of process modules 724 to 726 by the second robot 732. The processed wafers from the second group of process modules 724 to 726 are then transferred back to their original FOUPs 760 disposed at the second FOUP ports 7311 to 7314 by the second robot 732. Each of the FOUPs 760 remains at one of the first FOUP ports 7111 to 7114 and the second FOUP ports 7311 to 7314 when the wafers are processed in the first and second process modules 721 to 726. When all the wafers in one FOUP are processed and loaded back to the FOUP, the FOUP is then removed from the FOUP port.

Compared to the illustrated example of FIG. 1 (i.e., five process modules are installed), the track system 700 shown in FIG. 7 fully utilizes all space in the process zone 720 (i.e., six process modules are installed). The track system 700 shown in FIG. 7 may increase the wafer processing rate by 20%. Furthermore, in the illustrated example of FIG. 7, since the speed of the first robot 712 and the second robot 732 is no longer a bottleneck for the wafer processing, the transferring time of the first robot 712 and the second robot 732 may be set at more than 3 seconds (such as 4 to 6 seconds) to decrease the possibility of wafer breakage issues. Therefore, the track system 700 shown in FIG. 7 has increased productivity of wafer processing as compared to the track system 100 shown in FIG. 1.

Compared to the illustrated example of FIG. 5, the track system 700 shown in FIG. 7 has FOUP ports functioning as both inbound FOUP ports and outbound FOUP ports. No FOUP exchanger is required for the track system 700 shown in FIG. 7 to exchange the FOUPs at the FOUP ports. Therefore, the track system 700 shown in FIG. 7 has increased space efficiency as compared to the track system 500 shown in FIG. 5.

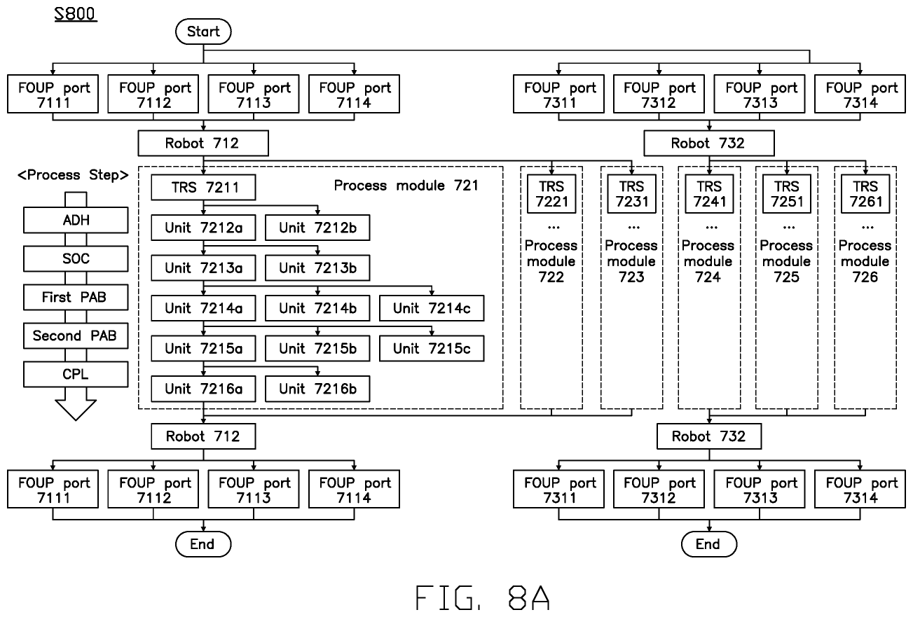

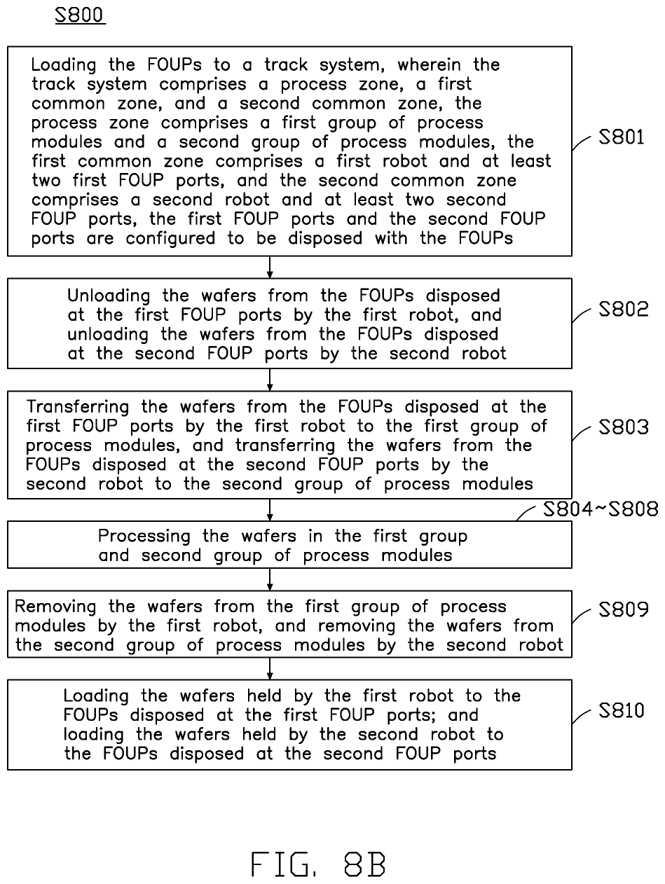

Referring to FIGS. 8A and 8B, a schematic flow and a flowchart of a method S800 of processing semiconductor wafers held by a plurality of FOUPs according to an example embodiment of the present disclosure are illustrated. The method S800 of FIGS. 8A and 8B includes steps S801 to S810. In step S801, the FOUPs are loaded to a track system. The track system of the illustrated example of FIGS. 8A and 8B may be referred to the track system 700 shown in FIG. 7. The track system 700 includes a process zone 720, a first common zone 710, and a second common zone 730. The process zone 720 includes a first group of process modules 721 to 723 and a second group of process modules 724 to 726. The first common zone 710 comprises a first robot 712 and at least two first FOUP ports 7111 to 7114. The second common zone 730 includes a second robot 732 and at least two second FOUP ports 7311 to 7314. The first FOUP ports 7111 to 7114 and the second FOUP ports 7311 to 7314 are configured to be disposed with the FOUPs 760. Each of the at least two first FOUP ports (i.e., FOUP ports 7111 to 7114) functions as an inbound FOUP port for disposing the FOUPs holding a plurality of unprocessed wafers and an outbound FOUP port for disposing the FOUPs holding processed wafers. Each of the at least two second FOUP ports (i.e., FOUP ports 7311 to 7314) also functions as an inbound FOUP port for disposing the FOUPs holding a plurality of unprocessed wafers and an outbound FOUP port for disposing the FOUPs holding processed wafers. The FOUPs are loaded to each of the first FOUP ports (i.e., FOUP ports 7111 to 7114) and each of the second FOUP ports (i.e., FOUP ports 7311 to 7314) of the track system 700.

In step S802, the wafers are unloaded from the FOUPs 760 disposed at the first FOUP ports (i.e., FOUP ports 7111 to 7114) by the first robot 712, and unloaded from the FOUPs disposed at the second FOUP ports (i.e., FOUP ports 7311 to 7314) by the second robot 732.

In step S803, the wafers from the FOUPs 760 disposed at the first FOUP ports (i.e., FOUP ports 7111 to 7114) are transferred to the first group of process modules 721 to 723 by the first robot 712, and wafers from the FOUPs disposed at the second FOUP ports (i.e., FOUP ports 7311 to 7314) are transferred to the second group of process modules 724 to 726 by the second robot 732. Each of the process modules 721 to 726 includes a transition stage (TRS) 7211 to 7261 respectively. The wafers are transferred to the TRS 7211 to 7261 of each of the process modules 721 to 726.

In steps S804 to S808, the wafers are processed in the first group and the second group of process modules 721 to 726. As shown in FIG. 8A, each of the process modules 721 to 726 includes a plurality of units to perform an adhesion (ADH) process, a spin on coating (SOC) process, at least one post apply baking (PAB) process (e.g., a first PAB process and a second PAB process), and a chill plate (CPL) process. Using the process module 721 as an example, the process module 721 includes units 7212a and 7212b to perform the ADH process, units 7213a and 7213b to perform the SOC process, units 7214a to 7214c to perform the first PAB process, units 7215a to 7215c to perform the second PAB process, and units 7216a and 7216b to perform the CPL process. Each unit in the same process has the same function. The steps S804 to S808 of shown in FIGS. 8A and 8B are similar to the steps S604 to S608 shown in FIGS. 6A and 6B without further description herein.

In step S809, the wafers are removed from the first group of process modules 721 to 723 by the first robot 712, and from the second group of process modules 724 to 726 by the second robot 732.

In step S810, the processed wafers held by the first robot 712 are loaded to the FOUPs 760 disposed at the first FOUP ports, and the processed wafers held by the second robot 732 are loaded to the FOUPs 760 disposed at the second FOUP ports. Specifically, when all the wafers in a FOUP are transferred to the process zone 720, the FOUP remains at the same FOUP port waiting to be loaded with processed wafers. For example, the FOUP carrying unprocessed wafers at the FOUP port 7111 may later be loaded with processed wafers at the FOUP port 7111.

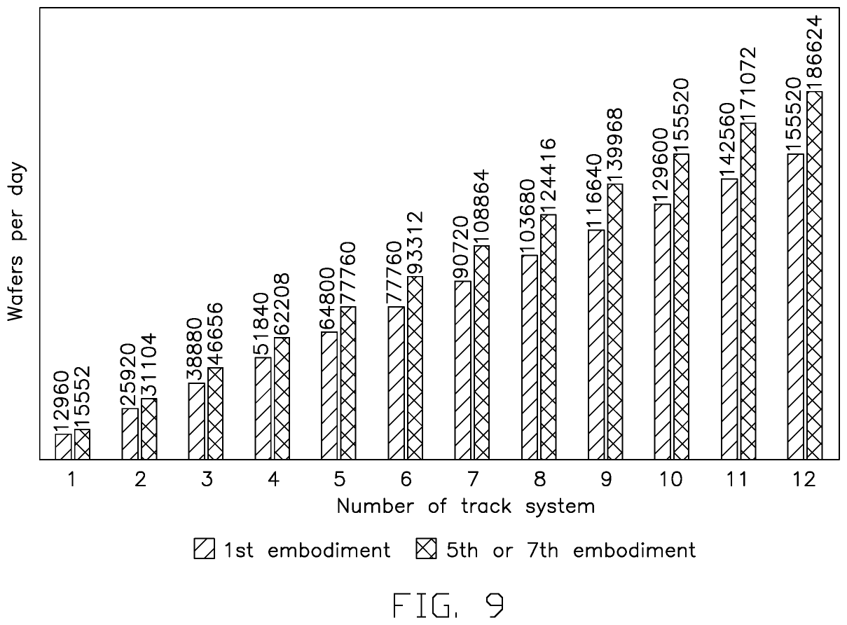

Referring to FIG. 9, productivities for the track systems of the illustrated examples of FIGS. 1, 5, 7, are illustrated. If the track system 100 shown in FIG. 1 (i.e., five process modules) may process 600 wafers per hour, 14400 wafers may be processed per day by the track system 100 at 100% production efficiency. However, due to the breakdown of the track system 100 or shortage of the FOUPs, the production efficiency might drop to 90% (i.e., 12960 wafers per day). For the track system 500 shown in FIG. 5 or the track system 700 shown in FIG. 7 (i.e., six process modules), 17280 wafers may be processed per day at 100% production efficiency, and 15552 at 90% production efficiency. As shown in FIG. 9, ten track systems of the illustrated example of FIG. 5 or FIG. 7 (i.e., six process modules) may process the same amount of wafers (e.g., 155520 wafers) with twelve track systems of the illustrated example of FIG. 1 (i.e., five process modules).

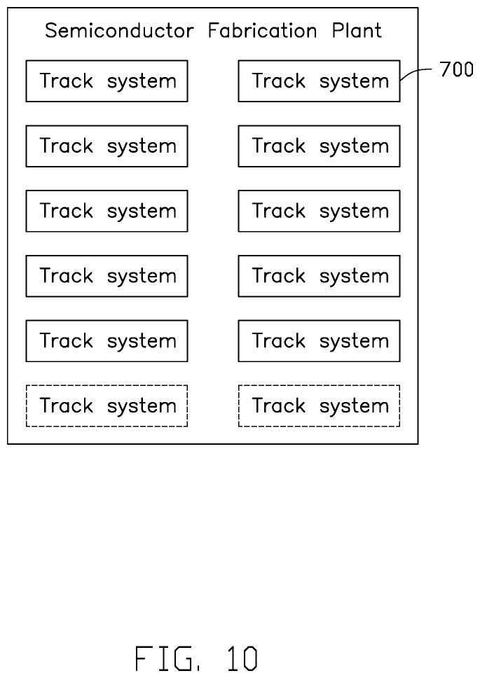

Referring to FIG. 10, the arrangement of the track systems 700 shown in FIG. 7 in a semiconductor fabrication plant is illustrated. As described above, the track system 700 shown in FIG. 7 has increased space efficiency. In a semiconductor fabrication plant that may install ten track systems of the illustrated example of FIG. 1 or FIG. 5, twelve track systems 700 shown in FIG. 7 may be installed. Therefore, the space of the semiconductor fabrication plant may be efficiently utilized, and the manufacture cost of the semiconductor fabrication plant may be reduced.

As described above, the track system of the embodiments of the present disclosure has two common zones respectively integrated with two groups of process modules. The track system allows full utilization of the space of the process zone in the track system. Therefore, the track system of the embodiments of the present disclosure has increased productivity and space efficiency.

The embodiments shown and described above are only examples. Many details are often found in the art such as the other features of a track system and a method of processing semiconductor wafers. Therefore, many such details are neither shown nor described. Even though numerous characteristics and advantages of the present technology have been set forth in the foregoing description, together with details of the structure and function of the present disclosure, the disclosure is illustrative only, and changes may be made in the detail, especially in matters of shape, size, and arrangement of the parts within the principles of the present disclosure, up to and including the full extent established by the broad general meaning of the terms used in the claims. It will therefore be appreciated that the embodiments described above may be modified within the scope of the claims.

What is claimed is:

1. A track system for processing semiconductor wafers held by a plurality of front opening universal pods (FOUPs), the track system comprising:
a process zone comprising a first group of process modules and a second group of process modules, each of the process modules is configured to process the wafers;
a first common zone coupled to the first group of process modules of the process zone, the first common zone comprising a first robot and at least two first FOUP ports, wherein each of the first FOUP ports is configured to be disposed with one of the plurality of FOUPs, the first robot is configured to transfer the wafers between the FOUPs disposed at the first FOUP ports and the first group of process modules; and
a second common zone coupled to the second group of process modules of the process zone, the second common zone comprising a second robot and at least two second FOUP ports, wherein each of the second FOUP ports is configured to be disposed with one of the plurality of FOUPs, the second robot is configured to transfer the wafers between the FOUPs disposed at the second FOUP ports and the second group of process modules.

2. The track system of claim 1, wherein the at least two first FOUP ports comprise at least one inbound FOUP port and at least one outbound FOUP port, the inbound FOUP port is configured to be disposed with the FOUPs holding unprocessed wafers, and the outbound FOUP port is configured to be disposed with the FOUPs holding processed wafers.

3. The track system of claim 1, wherein the at least two second FOUP ports comprise at least one inbound FOUP port and at least one outbound FOUP port, the inbound FOUP port is configured to be disposed with the FOUPs holding unprocessed wafers, and the outbound FOUP port is configured to be disposed with the FOUPs holding processed wafers.

4. The track system of claim 1, wherein the process zone has a first side and a second side parallel to the first side, the first FOUP ports of the first common zone are disposed along the first side of the process zone, and the second FOUP ports of the second common zone are disposed along the second side of the process zone.

5. The track system of claim 1, wherein each of the first robot and the second robot comprises a guiding rail and a robot hand coupled to the guiding rail, and the robot hand is configured to move the wafers along the guiding rail.

6. The track system of claim 1, wherein each of the process modules in the first and second groups comprises a plurality of units configured to process the wafers, and each of the units of the process modules is configured to perform at least one of an adhesion (ADH) process, a spin on coating (SOC) process, at least one post apply baking (PAB) process and a chill plate (CPL) process.

7. The track system of claim 6, wherein each of the process modules in the first and second groups further comprises a transition stage (TRS) configured to be disposed with the wafers before the wafers are transferred to the units.

8. The track system of claim 1, wherein the at least two first FOUP ports comprise two inbound FOUP ports and two outbound FOUP ports, and the first group of process modules comprises three process modules.

9. The track system of claim 8, further comprising a first FOUP exchanger coupled to the first common zone and configured to exchange the FOUPs among the first FOUP ports.

10. The track system of claim 1, wherein the at least two second FOUP ports comprise two inbound FOUP ports and two outbound FOUP ports, the second group of process modules comprises three process modules.

11. The track system of claim 10, further comprising a second FOUP exchanger coupled to the second common zone and configured to exchange the FOUPs among the second FOUP ports.

12. The track system of claim 1, wherein each of the at least two first FOUP ports functions as an inbound FOUP port for disposing the FOUPs holding a plurality of unprocessed wafers and an outbound FOUP port for disposing the FOUPs holding processed wafers.

13. The track system of claim 12, wherein the at least two first FOUP ports comprise four FOUP ports, and the first group of process modules comprises three process modules.

14. The track system of claim 1, wherein each of the at least two second FOUP ports functions as an inbound FOUP port for disposing the FOUPs holding a plurality of unprocessed wafers and an outbound FOUP port for disposing the FOUPs holding processed wafers.

15. The track system of claim 14, wherein the at least two second FOUP ports comprise four FOUP ports, and the second group of process modules comprises three process modules.

16. A method of processing semiconductor wafers held by a plurality of front opening universal pods (FOUPs), comprising:
loading the FOUPs to a track system, wherein the track system comprises a process zone, a first common zone, and a second common zone, the process zone comprises a first group of process modules and a second group of process modules, the first common zone comprises a first robot and at least two first FOUP ports, and the second common zone comprises a second robot and at least two second FOUP ports, the first FOUP ports and the second FOUP ports are configured to be disposed with the FOUPs;
unloading the wafers from the FOUPs disposed at the first FOUP ports by the first robot, and unloading the wafers from the FOUPs disposed at the second FOUP ports by the second robot;
transferring the wafers from the FOUPs disposed at the first FOUP ports by the first robot to the first group of process modules, and transferring the wafers from the FOUPs disposed at the second FOUP ports by the second robot to the second group of process modules;
processing the wafers in the first group and the second group of process modules;
removing the wafers from the first group of process modules by the first robot, and removing the wafers from the second group of process modules by the second robot; and
loading the processed wafers held by the first robot to the FOUPs disposed at the first FOUP ports, and loading the processed wafers held by the second robot to the FOUPs disposed at the second FOUP ports.

17. The method of claim 16, wherein the at least two first FOUP ports and the at least two second FOUP ports respectively comprise at least one inbound FOUP port and at least one outbound FOUP port, the inbound FOUP port is configured to be disposed with the FOUPs holding unprocessed wafers, and the outbound FOUP port is configured to be disposed with the FOUPs holding processed wafers, the track system further comprises a first FOUP exchanger coupled to the first common zone and a second FOUP exchanger coupled to the second common zone, and the method further comprising a step of:
transferring the FOUPs from the inbound FOUP port of the first FOUP ports to the outbound FOUP port of the first FOUP ports by the first FOUP exchanger, and transferring the FOUPs from the inbound FOUP port of the second FOUP ports to the outbound FOUP port of the second FOUP ports by the second FOUP exchanger.

18. The method of claim 16, wherein each of the at least two first FOUP ports and the at least two second FOUP ports functions as an inbound FOUP port for disposing the FOUPs holding a plurality of unprocessed wafers and an outbound FOUP port for disposing the FOUPs holding processed wafers.

19. The method of claim 16, wherein the at least two first FOUP ports comprise four FOUP ports, and the first group of process modules comprises three process modules.

20. The method of claim 16, wherein the at least two second FOUP ports comprise four FOUP ports, and the second group of process modules comprises three process modules.
